(19) United States
(12) Patent Application Publication
(10) Pub. No.: US 2026/0160842 A1
(43) Pub. Date: Jun. 11, 2026

(54) SYSTEM AND METHOD TO COMBINE DIFFERENT MULTI-ECHO IMAGES

(71) Applicant: NEW YORK SOCIETY FOR THE RELIEF OF THE RUPTURED AND CRIPPLED, MAINTAINING THE HO, New York, NY (US)

(72) Inventors: Ek Tsoon Tan, Westbury, NY (US); Darryl B. Sneag, Plainview, NY (US)

(21) Appl. No.: 19/123,976

(22) PCT Filed: Nov. 3, 2023
(86) PCT No.: PCT/US2023/036765

§ 371 Date: Apr. 24, 2025

Related U.S. Application Data
(60) Provisional application No. 63/423,784, filed on Nov. 8, 2022.
(60) Provisional application No. 63/481,283, filed on Jan. 24, 2023.

(51) Int. Cl. G01R 33/56; G01R 33/561

(52) U.S. Cl. CPC G01R 33/5608; G01R 33/5613; G01R 33/5615

(57) ABSTRACT

A method includes: acquiring magnetic resonance (MR) signals from a subject placed in a magnet of a MR scanner, wherein the MR signals are in response to radio frequency (RF) irradiation of the subject using a multi-echo MR imaging sequence; based on the acquired MR signals, obtaining a set of MR images that each correspond to a respective echo of the multi-echo MR imaging sequence; and geometrically combining at least two MR image from the set of MR images such that a combined image is generated with a first metric of signal-to-noise ratio and a second metric of contrast ratio both improved over those of each of the at least two MR images, wherein said geometrically combining comprises: generating an inverse representation for each of the at least two MR images; and summing respective inverse representations of the at least two MR images.

### CROSS REFERENCE TO RELATED APPLICATIONS

This application claims the priority benefit of U.S. Provisional Application No. 63/423,784, filed Nov. 8, 2022, and U.S. Provisional Application No. 63/481,283, filed Jan. 24, 2023, the content of each of which is incorporated by reference in its entirety herein.

### TECHNICAL FIELD

This description generally relates to magnetic resonance imaging.

### BACKGROUND

Combining multiple images acquired from different modalities or using different techniques can be useful for producing a secondary image that is more optimal for radiological assessment. In the context of magnetic resonance imaging (MRI), several techniques can be employed for image combination including, for example, averaging, weighted averaging, and more advanced techniques such as multi-channel parallel imaging and multi-echo imaging.

Averaging can involve, for example, adding the pixel values of multiple images and dividing the result by the number of images. Averaging can improve signal-to-noise ratio (SNR) by reducing the impact of noise in the combined image. Weighted averaging is similar to averaging, but can assign different weights to be assigned to each image, thereby allowing certain image(s) to be emphasized.

Multi-channel parallel imaging techniques, such as SENSE (SENSitivity Encoding) and GRAPPA (GRid-based Parallel Acquisition), can combine data from multiple receiver coils to improve signal-to-noise ratio (SNR) and image quality. These techniques can be particularly useful for MRI applications where multiple receiver coils are used to acquire data simultaneously.

Multi-echo imaging involves acquiring multiple echoes for each imaging slice and may involve combining the images from these echoes to improve SNR. This technique can be particularly useful for imaging tissues with low intrinsic contrast, as the SNR and/or the contrast-to-noise ratio (CNR) can be improved by combining images from multiple echoes.

Overall, image combination can be a useful tool for improving the quality and usefulness of medical images, and can be applied in a variety of imaging modalities and applications.

### SUMMARY

In one aspect, some implementations provide a method that includes: acquiring magnetic resonance (MR) signals from a subject placed in a magnet of a MR scanner, wherein the MR signals are in response to radio frequency (RF) irradiation of the subject using a multi-echo MR imaging sequence; obtaining a set of MR images from the acquired MR signals wherein each image corresponds to a respective echo of the multi-echo MR imaging sequence; and geometrically combining at least two MR images from the set of MR images such that a combined image is generated with a first metric of signal-to-noise ratio and a second metric of contrast ratio, both improved as compared to the first metric and the second metric of each of the at least two MR images, wherein said geometric combination comprises: generating an inverse representation for each of the at least two MR images; and summing respective inverse representations of the at least two MR images.

Implementations may include one or more of the following features.

Geometric combination may further include: generating an inverse representation of results of said summing. The method may further include: generating a display of the combined image, and providing the display to a medical practitioner. Generating the inverse representation may include: performing an inverse operation of pixels of an MR image from the set of MR images. The method may further include: adding a non-zero constant to the pixels of the MR image before performing the inverse operation of pixels of the MR image.

The set of MR images may include T₂-weighted or T₂*-weighted images. The multi-echo MR imaging sequence may include: a SSFP (steady-state free precession) sequence, a MERGE (multiple echo recombined gradient echo) sequence, or a MEDIC sequence (multiple echo data image combination).

In another aspect, some implementations provide a magnetic resonance scanner, comprising: a main magnet configured to generate a volume of magnetic field, the main magnet including a bore area sized to accommodate at least a body part of a subject; a radio frequency (RF) coil assembly configured to irradiate the body part of the subject in the magnet; a gradient coil assembly configured to generate gradient pulses that provide perturbations to the volume of magnetic field such that MR signals are emitted from the body part and are subsequently acquired by the coil assembly; and a control unit in communication with the gradient coils and the coil assembly and configured to drive the RF coil assembly and the gradient coil assembly, and perform operations of: acquiring the magnetic resonance (MR) signals from the body part of the subject placed in the magnet, wherein the MR signals are in response to radio frequency (RF) irradiation of the subject using a multi-echo MR imaging sequence; obtaining a set of MR images based on the acquired MR signals wherein each image corresponds to a respective echo of the multi-echo MR imaging sequence; and geometrically combining at least two MR images from the set of MR images such that a combined image is generated with a first metric of signal-to-noise ratio and a second metric of contrast ratio both improved as compared to the first and second metric of each of the at least two MR images, wherein said geometric combination comprises: generating an inverse representation for each of the at least two MR images; and summing respective inverse representations of the at least two MR images.

Implementations may include one or more of the following features.

Geometric combination may further include: generating an inverse representation of results of said summing. The operations may further include: generating a display of the combined image, and providing the display to a medical practitioner. Generating the inverse representation may include: performing an inverse operation of pixels of an MR image from the set of MR images. The operations may further include: adding a non-zero constant to the pixels of the MR image before performing the inverse operation of pixels of the MR image.

The set of MR images may include T₂-weighted or T₂*-weighted images. The multi-echo MR imaging sequence may include: a SSFP (steady-state free precession) sequence, a MERGE (multiple echo recombined gradient echo) sequence, or a MEDIC sequence (multiple echo data image combination).

In yet another aspect, some implementations provide a non-transitory computer-readable medium comprising software instructions which, when executed by one or more computer processors, cause the one or more computer processors to perform operations of: accessing magnetic resonance (MR) signals from a subject placed in a magnet of a MR scanner, wherein the MR signals are in response to radio frequency (RF) irradiation of the subject using a multi-echo MR imaging sequence; obtaining a set of MR images from the MR signals wherein each image corresponds to a respective echo of the multi-echo MR imaging sequence; and geometrically combining at least two MR image from the set of MR images such that a combined image is generated with a first metric of signal-to-noise ratio and a second metric of contrast ratio both improved when compared to the first metric and the second metric of each of the at least two MR images, wherein said geometric combination comprises: generating an inverse representation for each of the at least two MR images; and summing respective inverse representations of the at least two MR images.

Implementations may include one or more of the following features.

Geometric combination may further include: generating an inverse representation of results of said summing. The operations may further include: generating a display of the combined image, and providing the display to a medical practitioner. Generating the inverse representation may include: performing an inverse operation of pixels of an MR image from the set of MR images. The operations may further include: adding a non-zero constant to the pixels of the MR image before performing the inverse operation of pixels of the MR image.

The set of MR images may include T₂-weighted or T₂*-weighted images. The multi-echo MR imaging sequence may include: a SSFP (steady-state free precession) sequence, a MERGE (multiple echo recombined gradient echo) sequence, or a MEDIC sequence (multiple echo data image combination).

The details of one or more aspects of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

Embodiments will now be described, by way of example only, with reference to the drawings, in which:

FIG. 1 is a diagram illustrating an example of a work flow according to some implementations of the present disclosure.

FIG. 2 shows an example of a flow chart according to some implementations of the present disclosure.

FIGS. 3A to 3C show examples of signal-to-noise ratio (SNR) and contrast ratio (CR) in some implementations of the present disclosure.

FIGS. 4A to 4D show examples of MRI images of a subject's elbow generated by some implementations of the present disclosure.

FIGS. 5A to 5D show examples of MRI images of a subject's forearm generated by some implementations of the present disclosure.

FIGS. 6A to 6D show examples of MRI images of a subject's calf generated by some implementations of the present disclosure.

FIGS. 7A to 7E show examples of MRI images of a subject's lumbosacral plexus generated by some implementations of the present disclosure.

FIG. 8 shows an example of a computer system used by some implementations of the present disclosure.

Like reference symbols in the various drawings indicate like elements.

### DETAILED DESCRIPTION

The present disclosure describes a method for combining multi-echo MR images that not only improves signal-to-noise ratio (SNR), but also preserves the signal contrast of the last echo from the multi-echo acquisition so that the resultant image provides a better trade-off between SNR and signal contrast.

By way of illustration, multi-image combination is often employed in quantitative encoding for imaging. In quantitative encoding, images may be combined to also provide a higher quality or lower noise image, which may be more useful for radiologic interpretation than the individual image obtained from an individually encoded image.

Examples of quantitative encoding include diffusion-weighted imaging (DWI), magnetic resonance elastography (MRE), phase-contrast (PC) imaging (often used to encode velocity), and multispectral imaging (MSI) techniques. In the example of DWI, trace images are frequently created before multiplicatively combined as a product of all images and then processed with the nth root of the product, where n is the number of source DWI images. In the example of MSI, multi-spectral images are combined using a square-root of the sum of squares of each individual frequency image. Indeed, the sum-of-squares method is also a commonly applied method for combining multi-channel phased-array coil images, in addition to combining multi-echo images. Another example for combining images is taking the mean or arithmetic average of all images. In addition, as MR images are typically obtained in complex space (with real and imaginary components), the real and imaginary components are often first combined by taking the magnitude of both real and imaginary components. One variant of such complex image combination is used in multi-echo “Dixon” techniques that attempt to separate fat and water images that have varying phase in different echoes acquired with distinct echo times.

Some implementations of the present disclosure include a method to combine images from a multi-echo image sequence in a manner that provides higher SNR than the last echo in the image sequence, while preserving the contrast of the last echo in the image sequence. The combination can be implemented with ease, and is analogous to the calculation of net resistance from parallel resistors. In calculating parallel resistance, the inverse of net resistance is the sum of the inverse of resistances from individual resistors.

In this calculation, the conductivity of parallel resistors is the sum of individual conductivities of the resistors, whereby conductivity is the inverse of resistivity. In our proposed method, called geometric combination, the net image is the inverse of the sum of the inverse of the individual images. The method of parallel resistivity has the effect of making the combined resistance similar to that of the lowest resistivity of the parallel resistors. Similarly, the geometric combination has the effect of preserving the lowest signal intensity from the individual images, which in multi-echo imaging, contains the desired image contrast. Hence, applying the geometric combination in T₂ or T₂*-weighted multi-echo imaging preserves the lowest signal intensity and therefore has higher image contrast compared to each individual image. As geometric combination uses all images, the net SNR will also be higher than that of the individual image from the last echo.

Therefore, the implementations add significantly more to conventional combination by providing an improved trade-off of SNR and contrast ratio. The technical improvement is evidenced by the enhanced ability of the resulting images to delineate otherwise obfuscated anatomical structures. The significant improvement can be realized without the added expense of multi-channel receiver hardware and can leverage existing computational infrastructure for image reconstruction. For example, the implementations can be incorporated by existing scanner systems without requiring extensive reconfiguration or additional hardware. As such, the geometric combination may be implemented on a vendor-provided image reconstruction software, or offline on separate workstations that can read MRI images and perform the arithmetic combination as described above and shown subsequently in the equations. Indeed, an existing installation, including the MRI scanner and accompanying image reconstruction software, can be reconfigured with relatively minor investment to reap the full benefit of objectively discernable improvement (e.g., SNR and signal contrast) of the disclosed implementations. Significantly, the disclosed implementations operate on MR signals received in real-time and in response to RF excitation pulses. In various implementations, both the MR signals and the RF excitation pulses oscillate around the Lamor frequency dictated by the strength of the main magnetic field. The handling of the MR signals and the RF excitation pulses entail dedicated and specialized circuitry (e.g., coils, balun transformers, pre-amplifiers).

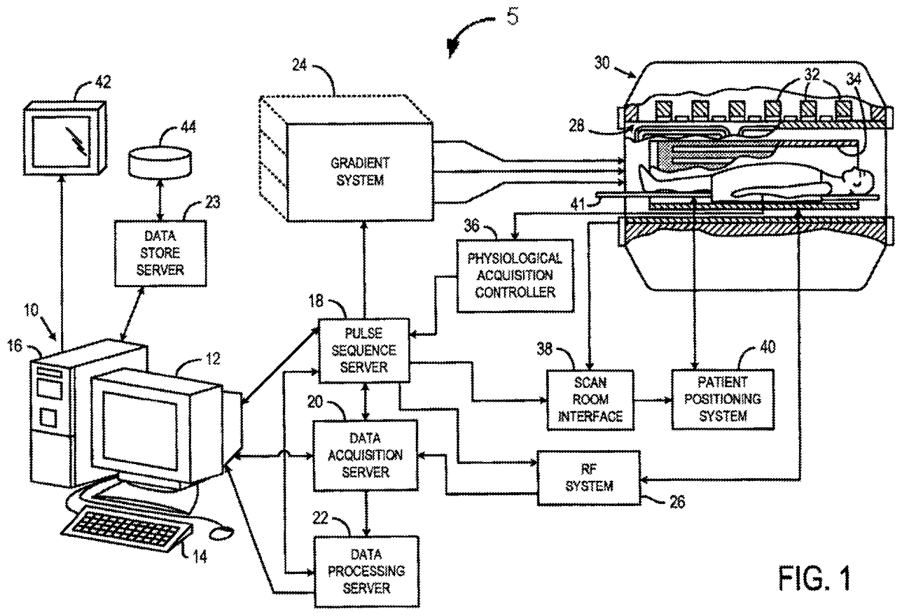

FIG. 1 shows an example of a magnetic resonance imaging (MRI) system 5 with a solenoid magnet for imaging knee joints. The MRI system 5 includes a workstation 10 having a display 12 and a keyboard 14. The Workstation 10 includes a processor 16 that is a commercially available programmable machine running a commercially available operating system. The workstation 10 provides the operator interface that enables scan prescriptions to be entered into the MRI system 5. The workstation 10 is coupled to four servers including a pulse sequence server 18, a data acquisition server 20, a data processing server 22, and a data store server 23. The work station 10 and each server 18, 20, 22 and 23 are connected to communicate with each other.

The pulse sequence server 18 functions in response to instructions downloaded from the workstation 10 to operate a gradient system 24 and an RF system 26. Gradient waveforms necessary to perform the prescribed scan are produced and applied to the gradient system 24 that excites gradient coils in an assembly 28 to produce the magnetic field gradients Gx, Gy and Gz used for position-encoding MR signals. The gradient coil assembly 28 forms part of a magnet assembly 30 that includes a polarizing magnet 32 and a whole-body RF coil 34.

RF excitation waveforms are applied to the RF coil 34 by the RF system 26 to perform the prescribed magnetic resonance pulse sequence. Responsive MR signals detected by the RF coil 34 or a separate local coil (not shown in FIG. 1) are received by the RF system 26, amplified, demodulated, filtered, and digitized under direction of commands produced by the pulse sequence server 18. The RF system 26 includes an RF transmitter for producing a wide variety of RF pulses used in MR pulse sequences. The RF transmitter is responsive to the scan prescription and direction from the pulse sequence server 18 to produce RF pulses of the desired frequency, phase and pulse amplitude waveform. The generated RF pulses may be applied to the whole body RF coil 34 or to one or more local coils or coil arrays (not highlighted in FIG. 1).

The RF system 26 also includes one or more RF receiver channels. Each RF receiver channel includes an RF amplifier that amplifies the MR signal received by the coil to which it is connected and a detector that detects and digitizes the I and Q quadrature components of the received MR signal.

The pulse sequence server 18 also optionally receives patient or subject data from a physiological acquisition controller 36. The controller 36 receives signals from a number of different sensors connected to the patient, such as ECG signals from electrodes or respiratory signals from a bellows. Such signals are typically used by the pulse sequence server 18 to synchronize, or “gate”, the performance of the scan with the subject's respiration or heartbeat.

The pulse sequence server 18 also connects to a scan room interface circuit 38 that receives signals from various sensors associated with the condition of the patient and the magnet system. It is also through the scan room interface circuit 38 that a patient positioning system 40 receives commands to move the patient to desired positions during the scan by translating the patient table 41.

The digitized MR signal samples produced by the RF system 26 are received by the data acquisition server 20. The data acquisition server 20 operates in response to instructions downloaded from the workstation 10 to receive the real-time MR data and provide buffer storage such that no data is lost by data overrun. In some scans the data acquisition server 20 does little more than pass the acquired MR data to the data processor server 22. However, in scans that require information derived from acquired MR data to control the further performance of the scan, the data acquisition server 20 is programmed to produce such information and convey it to the pulse sequence server 18. For example, during prescans, MR data is acquired and used to calibrate the pulse sequence performed by the pulse sequence server 18. Also, navigator signals may be acquired during a scan and used to adjust RF or gradient system operating parameters or to control the view order in which k-space is sampled. In all these examples the data acquisition server 20 acquires MR data and processes it in real-time to produce information that is used to control the scan.

The data processing server 22 receives MR data from the data acquisition server 20 and processes it in accordance with instructions downloaded from the workstation 10. Such processing may include, for example, Fourier transformation of raw k-space MR data to produce two or three dimensional images, the application of filters to a reconstructed image, the performance of a back projection image reconstruction of acquired MR data, the calculation of functional MR images, the calculation of motion or flow images, and the like.

Images reconstructed by the data processing server 22 are conveyed back to the workstation 10 where they are stored. Real-time images are stored in a data base memory cache (not shown) from which they may be output to operator display 12 or a display 42 that is located near the magnet assembly 30 for use by physicians. Batch mode images or selected real time images are stored in a host database on disc storage 44. When such images have been reconstructed and transferred to storage, the data processing server 22 notifies the data store server 23 on the workstation 10. The Workstation 10 may be used by an operator to archive the images, produce films, or send the images via a network to other facilities.

As shown in FIG. 1, the RF system 26 may be connected to the whole body RF coil 34 while a transmitter section of the RF system 26 may connect to one RF coil and its receiver section may connect to a separate RF receive coil. Often, the transmitter section is connected to the whole body RF coil 34 and each receiver section is connected to a separate local coil. In this illustration, RF receive coil can be a phased array coil. In some cases, the phased array coil is a receive-only coil. In other cases, the phased array coil functions as both a transmitter and a receiver (also known as a transceiver).

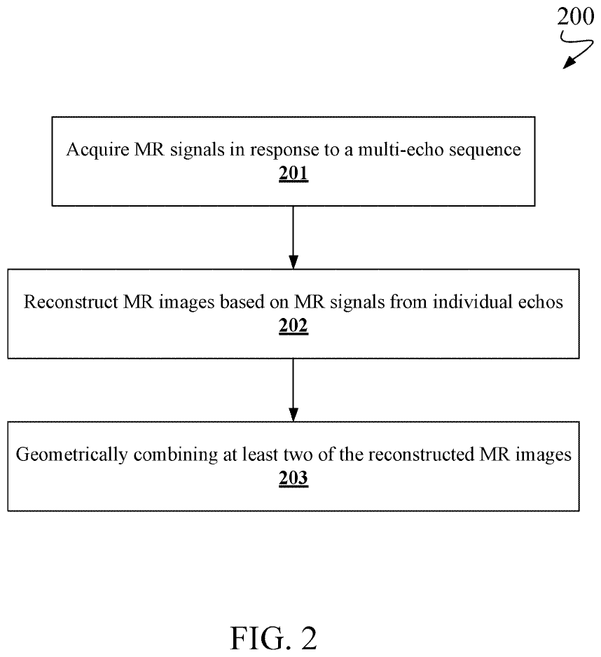

Referring to FIG. 2, some implementations of the present disclosure incorporate a geometric combination. As illustrated by flow chart 200, the implementations may initially acquire MR signals from a multi-echo MRI imaging sequence (201). Examples of multi-echo MR imaging sequence can include gradient recalled multi-echo sequences such as fast low angle shot (FLASH), multiple echo data image combination (MEDIC), multi-echo fast field echo (mFFE), and multiple echo recombined gradient echo (MERGE) techniques, as well as multi-echo steady-state free precession (SSFP) sequences such as dual-echo steady state free precession (DESS) techniques. The implementations may then reconstruct multi-echo images from the acquired MR signals encoding multi-echo data (202). The reconstruction may generate multiple images that each correspond to, for example, a distinct echo time (TE). In the case of a DESS technique, the reconstruction process can generate two images that correspond to, respectively, the first and the second echoes. Each image can contain, for example, a 2-D or 3-D matrix of image pixels. The implementations may then perform a geometric combination of the multiple images, thereby producing, for example, a single geometric combined image (203). Notably, the DESS technique is subset of the SSFP (steady-state free precession) sequence, which can include a TESS (triple echo steady state) sequence, and other multi-echo SSFP versions with more than two echoes.

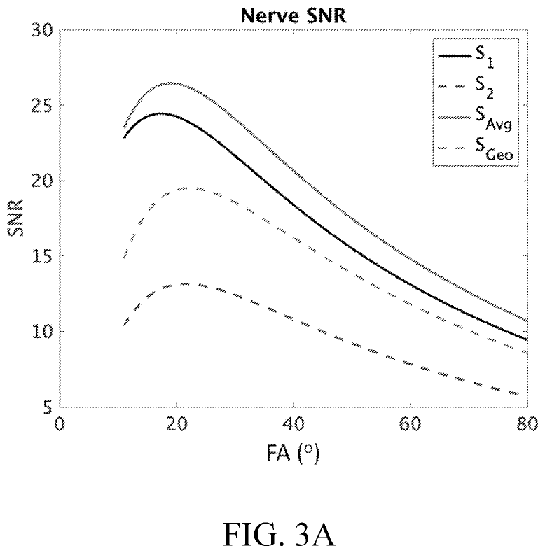

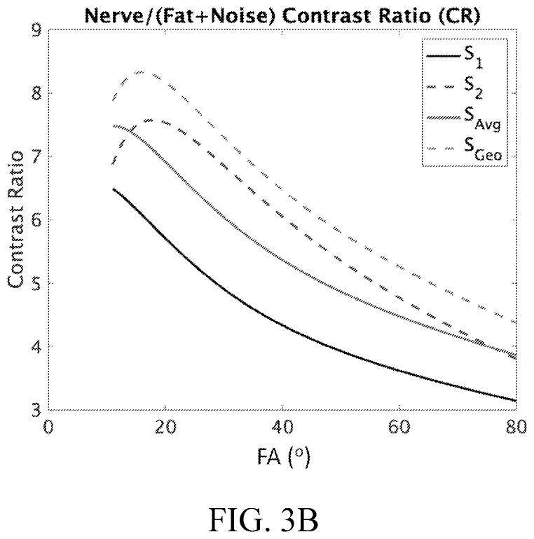

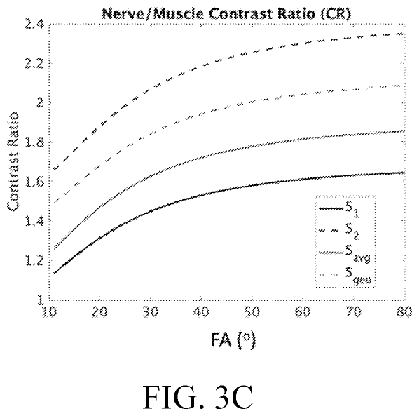

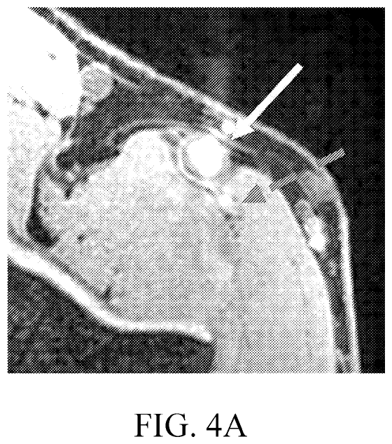

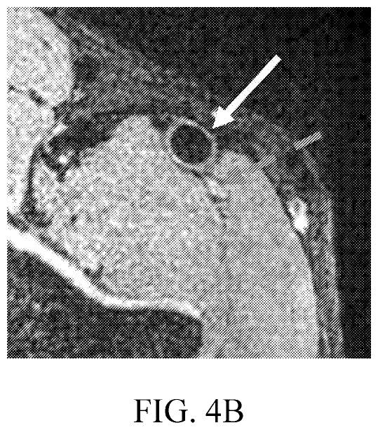

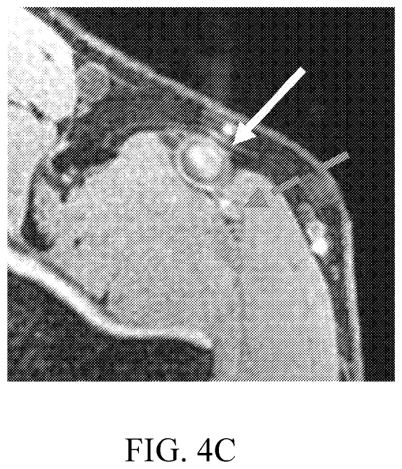

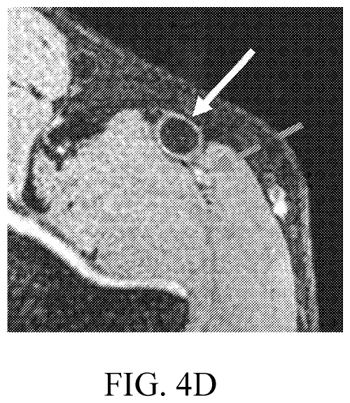

In more detail, when two images are geometrically combined, without loss of generality, the net signal Sₙₑₜ can be expressed as:

$${S}_{net} = 1 / ( 1 / {S}_{1} + 1 / {S}_{2} ) , \qquad ( 1 )$$

where S₁ and S₂ each correspond to the individual image signals from two echoes. For example, each individual image signal can correspond to a distinct echo of the multi-echo sequence. The image signals can refer to a reconstructed image that contains a 2-D or 3-D matrix of image pixels. Examples of the first image signals are shown in FIGS. 4A, 5A, and 6A, whereas the corresponding examples of the second image signals are shown in FIGS. 4B, 5B, and 6B. Moreover, FIG. 3A shows an example from a simulation illustrating the SNR for a simulated nerve region while FIGS. 3B and 3C show examples from the same simulation illustrating the contrast of the simulated nerve region relative to fat and muscle, respectively. The simulation cover both the first image signals (S₁) and the second images signals (S₂).

In equation (1), the inverse representation (e.g., 1/S₁ and 1/S₂) refers to a dot division in which the magnitude of each pixel is inverted. For clarity, the inverse representation does not refer to the inverse of a matrix.

Without loss of generality, when a number (e.g., n) of individual images are combined, the combination can be expressed as:

$${S}_{net} = 1 / {\sum }_{i}^{n} \frac{1}{{S}_{i}} , \qquad ( 2 )$$

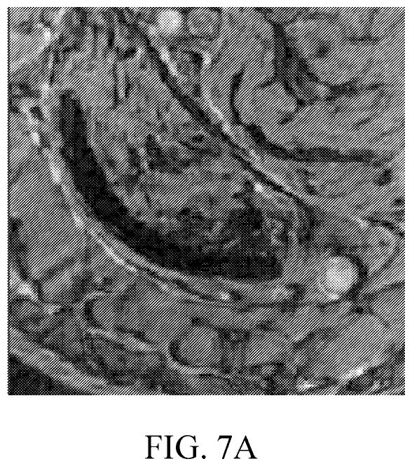

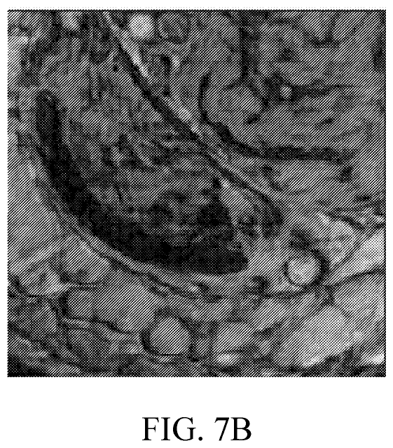

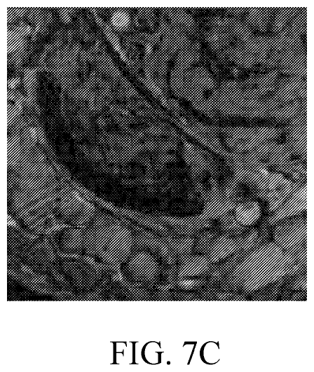

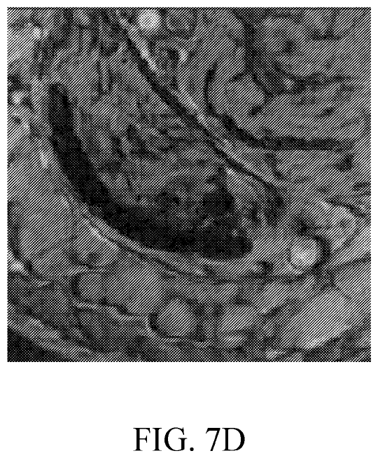

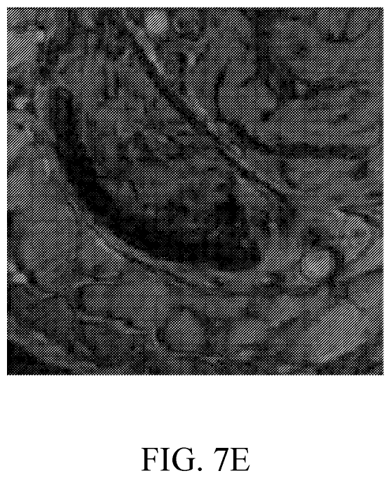

By way of illustration, FIGS. 7A, 7B, and 7C show examples of the first, second, and third image signals that respectively correspond to the first, second, and third echoes of a multi-echo sequence. FIG. 7E shows an example of the geometrically combined image based on inverse representations of the first, second, and third image signals.

The above formulation of the geometric combination can be observed by an alternative but equivalent formulation below. For instance, in the case of two image echoes, the net signal may also be expressed as:

$${S}_{net} = \frac{{S}_{1} \times {S}_{2}}{{S}_{1} + {S}_{2}} , \qquad ( 3 )$$

The implementations may add a small offset term in the denominator to avoid the divide-by-zero problem. In other words, the net signal Sₙₑₜ may alternatively be implemented by adding a small offset constant to the summed image signal prior to division. For example, for two echoes, the expression may become:

$${S}_{net}^{′} = \frac{{S}_{1} \times {S}_{2}}{{S}_{1} + {S}_{2} + ε} \qquad ( 4 )$$

For two or more echoes, the following formulation, that is not equivalent to the one above, may also be used:

$${S}_{net} = 1 / {\sum }_{i}^{n} \frac{1}{{S}_{i} + ε} , \qquad ( 5 )$$

where ε is a small constant, such as unity (1), or other amount sufficient to prevent a divide by zero condition.

Referring to FIGS. 3A to 3C, simulations demonstrate the superiority of the disclosed geometric imaging combination (GIC). In particular, a numerical simulation was conducted for a two-echo combination to investigate the performance of the disclosed GIC implementation. FIG. 3A shows that the SNR in the nerve region has been improved for the GIC implementation (dashed gray line) when compared to the SNR of the image signal based on the second echo (S₂). As expected, the SNR varies with respect to flip angle (FA). In terms of the contrast ratio of nerve over fat, FIG. 3B shows higher contrast ratio for both GIC and S₂ than that from the image signal based on the first echo (S₁) and the average between S₁ and S₂. As shown in FIG. 3B, this contrast ratio generally decreases with respect to the flip angle (FA). As to the nerve-to-muscle contrast ratio, FIG. 2C shows higher contrast ratio for both GIC and S₂ than that from the image signal based on the first echo (S₁) and the average between S₁ and S₂. As shown in FIG. 3C, this contrast ratio generally increases with respect to the flip angle (FA). Given the varied dependence of SNR and contrast ratio on the flipping angle, an optimal FA of 35° was used in these example experiments, the results of which are presented below.

FIGS. 4A to 4D show experimental results from applying the geometric imaging combination (GIC) when using the dual-echo steady-state free precession (DESS) technique on a subject's elbow. The DESS technique employs two echoes, in which the ratio of the signals from both echoes approximately follows the T₂ exponential decay. FIG. 4A shows the image signal for the first echo (namely, S₁), while FIG. 4B shows the image signal of the second echo (namely, S₂). As revealed by comparing and contrasting FIGS. 4A and 4B, the image signal for the first echo (namely, S₁) exhibits rather poor vascular suppression (solid arrow), while the image signal of the second echo (namely, S₂) exhibits excellent vascular suppression (solid arrow) and better conspicuity of the median nerve (dashed arrow). FIG. 4C shows the arithmetic combined image, which continues to have poor vascular suppression but with an image contrast that is between the first and second echoes of FIGS. 4A and 4B. FIG. 4D shows the geometric combined image (GIC), which has an image contrast similar to that of the image signal of the second echo (FIG. 4B) but with higher SNR. Given the superior contrast while maintaining sufficient SNR, the overall image quality is thus improved, when compared to the arithmetic combination of FIG. 4C.

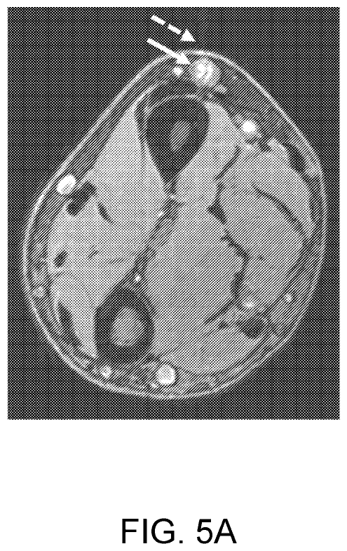

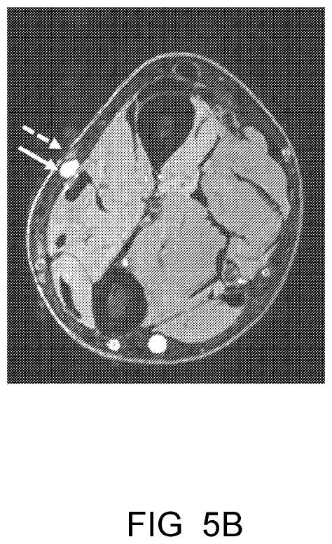

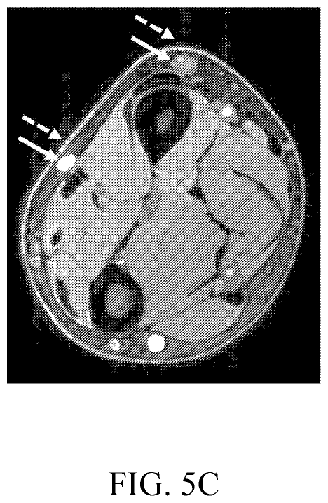

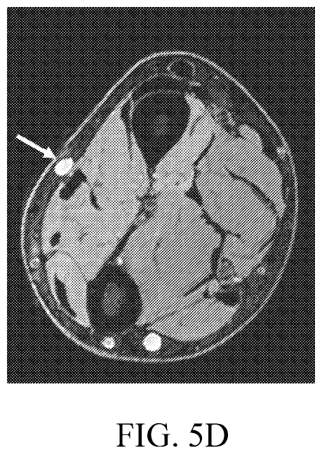

In addition, as DESS is a motion-sensitive technique, pulsation and other motion artifacts are frequently observed. As flow artifacts may manifest variably across images signals from different echoes, applying geometric image combination to DESS images has the effect of not only preserving T₂ contrast and increasing SNR, but also the effect of reducing flow artifacts, as revealed by FIGS. 5A to 5D. FIG. 5A shows the image signal for the first echo (namely, S₁) of the forearm, while FIG. 5B shows the image signal of the second echo (namely, S₂) of the same region. As revealed in FIG. 5A, the image signal for the first echo (namely, S₁) exhibits rather poor vascular suppression (solid arrow) and pronounced flow artifacts (dashed arrow). While the image signal of the second echo (namely, S₂) exhibits excellent vascular suppression (solid arrow), the unsuppressed vascular signal in S₂ retains the flow artifacts (dashed arrow). FIG. 5C shows the arithmetic combined image, which continues to have poor vascular suppression and residual flow artifacts. FIG. 5D shows the geometric combined image (GIC), which has an image contrast similar to that of the image signal of the second echo (FIG. 5B) but with less conspicuous flow artifacts even though the vessel is still unsuppressed. This improvement represents a technical effect of the proposed combination when compared with conventional combination. The technical effect of GIC is therefore not limited to providing a more balanced SNR and contrast ratio, but may also suppress undesired artifacts. As demonstrated above, the technical effect can also manifest in reduced motion artifacts (e.g., pulsatile blood flow).

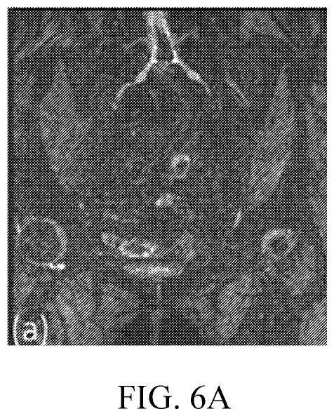

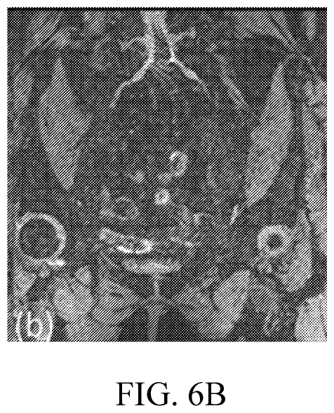

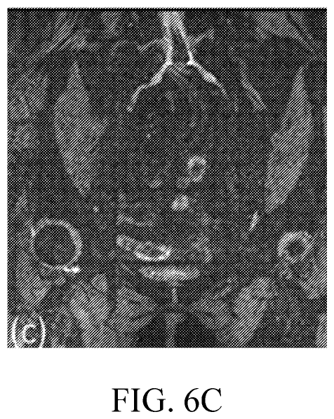

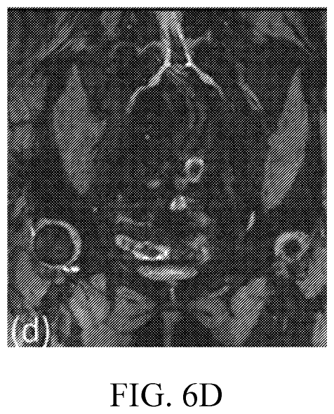

FIGS. 6A to 6D show results of applying the proposed geometric image combination to 3D DESS images in the lumbosacral plexus of a subject. FIG. 6A shows image signals from the 1^{st} echo (namely, S₁) while FIG. 6B shows image signals from the 2^{nd} echo (namely, S₂). FIG. 6C shows the arithmetic average of image signals of both echoes. FIG. 6D shows the geometric image combination (GIC) of image signals of both echoes.

The proposed GIC implementations can also be applied to image signals from multi-echo gradient echo sequences. FIGS. 7A to 7E show an example of applying the disclosed GIC implementation to a three-echo gradient-echo acquisition in the calf of a subject. In this three-echo gradient echo sequence, signal intensities decrease due to T₂* decay with increased echo time (TE). FIGS. 7A to 7C show image signals from the respective first, second and third echoes. FIG. 7D shows the combined image using the arithmetic combination while FIG. 7E shows the combined image using the proposed geometric image combination (GIC). Here, the arithmetic averaged image (FIG. 7D) produces higher SNR and similar image contrast to the middle echo image (FIG. 7B), whereas the geometric averaged image (FIG. 7E) produces higher SNR but similar image contrast to the longest echo image (FIG. 7C).

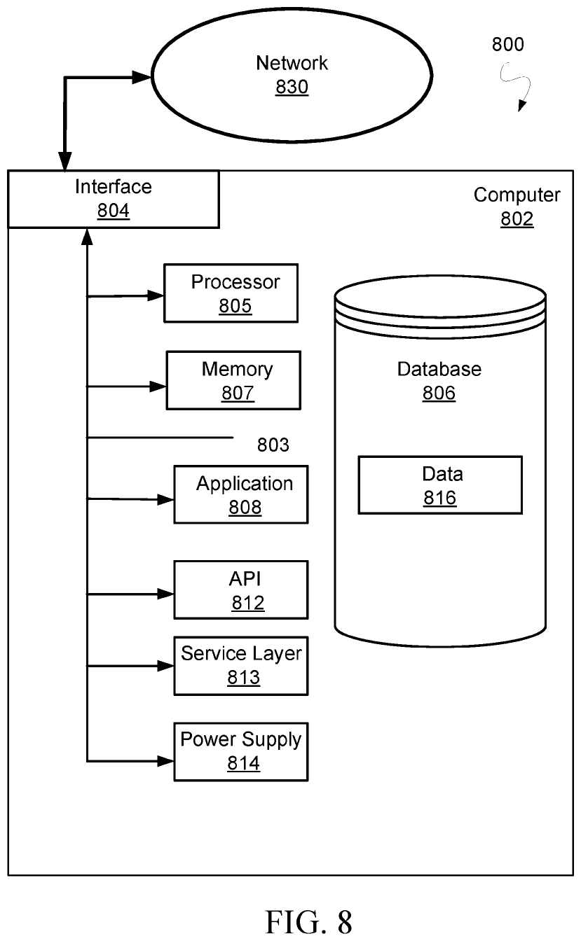

FIG. 8 is a block diagram 800 illustrating an example of a computer system 800 used to provide computational functionalities associated with described algorithms, methods, functions, processes, flows, and procedures, according to an implementation of the present disclosure. The illustrated computer 802 is intended to encompass any computing device such as a server, desktop computer, laptop/notebook computer, wireless data port, smart phone, personal data assistant (PDA), tablet computing device, one or more processors within these devices, another computing device, or a combination of computing devices, including physical or virtual instances of the computing device, or a combination of physical or virtual instances of the computing device. Additionally, the computer 802 can comprise a computer that includes an input device, such as a keypad, keyboard, touch screen, another input device, or a combination of input devices that can accept user information, and an output device that conveys information associated with the operation of the computer 802, including digital data, visual, audio, another type of information, or a combination of types of information, on a graphical-type user interface (UI) (or GUI) or other UI.

The computer 802 can serve in a role in a computer system as a client, network component, a server, a database or another persistency, another role, or a combination of roles for performing the subject matter described in the present disclosure. The illustrated computer 802 is communicably coupled with a network 830. In some implementations, one or more components of the computer 802 can be configured to operate within an environment, including cloud-computing-based, local, global, another environment, or a combination of environments.

The computer 802 is an electronic computing device operable to receive, transmit, process, store, or manage data and information associated with the described subject matter. According to some implementations, the computer 802 can also include or be communicably coupled with a server, including an application server, e-mail server, web server, caching server, streaming data server, another server, or a combination of servers.

The computer 802 can receive requests over network 830 (for example, from a client software application executing on another computer 802) and respond to the received requests by processing the received requests using a software application or a combination of software applications. In addition, requests can also be sent to the computer 802 from internal users, external or third-parties, or other entities, individuals, systems, or computers.

Each of the components of the computer 802 can communicate using a system bus 803. In some implementations, any or all of the components of the computer 802, including hardware, software, or a combination of hardware and software, can interface over the system bus 803 using an application programming interface (API) 812, a service layer 813, or a combination of the API 812 and service layer 813. The API 812 can include specifications for routines, data structures, and object classes. The API 812 can be either computer-language independent or dependent and refer to a complete interface, a single function, or even a set of APIs. The service layer 813 provides software services to the computer 802 or other components (whether illustrated or not) that are communicably coupled to the computer 802. The functionality of the computer 802 can be accessible for all service consumers using this service layer. Software services, such as those provided by the service layer 813, provide reusable, defined functionalities through a defined interface. For example, the interface can be software written in JAVA, C++, another computing language, or a combination of computing languages providing data in extensible markup language (XML) format, another format, or a combination of formats. While illustrated as an integrated component of the computer 802, alternative implementations can illustrate the API 812 or the service layer 813 as stand-alone components in relation to other components of the computer 802 or other components (whether illustrated or not) that are communicably coupled to the computer 802. Moreover, any or all parts of the API 812 or the service layer 813 can be implemented as a child or a sub-module of another software module, enterprise application, or hardware module without departing from the scope of the present disclosure.

The computer 802 includes an interface 804. Although illustrated as a single interface 804 in FIG. 8, two or more interfaces 804 can be used according to particular needs, desires, or particular implementations of the computer 802. The interface 804 is used by the computer 802 for communicating with another computing system (whether illustrated or not) that is communicatively linked to the network 830 in a distributed environment. Generally, the interface 804 is operable to communicate with the network 830 and comprises logic encoded in software, hardware, or a combination of software and hardware. More specifically, the interface 804 can comprise software supporting one or more communication protocols associated with communications such that the network 830 or interface's hardware is operable to communicate physical signals within and outside of the illustrated computer 802.

The computer 802 includes a processor 805. Although illustrated as a single processor 805 in FIG. 8, two or more processors can be used according to particular needs, desires, or particular implementations of the computer 802. Generally, the processor 805 executes instructions and manipulates data to perform the operations of the computer 802 and any algorithms, methods, functions, processes, flows, and procedures as described in the present disclosure.

The computer 802 also includes a database 806 that can hold data for the computer 802, another component communicatively linked to the network 830 (whether illustrated or not), or a combination of the computer 802 and another component. For example, database 806 can be an in-memory, conventional, or another type of database storing data consistent with the present disclosure. In some implementations, database 806 can be a combination of two or more different database types (for example, a hybrid in-memory and conventional database) according to particular needs, desires, or particular implementations of the computer 802 and the described functionality. Although illustrated as a single database 806 in FIG. 8, two or more databases of similar or differing types can be used according to particular needs, desires, or particular implementations of the computer 802 and the described functionality. While database 806 is illustrated as an integral component of the computer 802, in alternative implementations, database 806 can be external to the computer 802. As illustrated, the database 806 holds the previously described data 816 including, for example, demographic data, pre-operative data, perioperative data, and post-operative data as discussed in FIGS. 3A-7E.

The computer 802 also includes a memory 807 that can hold data for the computer 802, another component or components communicatively linked to the network 830 (whether illustrated or not), or a combination of the computer 802 and another component.

Memory 807 can store any data consistent with the present disclosure. In some implementations, memory 807 can be a combination of two or more different types of memory (for example, a combination of semiconductor and magnetic storage) according to particular needs, desires, or particular implementations of the computer 802 and the described functionality. Although illustrated as a single memory 807 in FIG. 8, two or more memories 807 or similar or differing types can be used according to particular needs, desires, or particular implementations of the computer 802 and the described functionality.

While memory 807 is illustrated as an integral component of the computer 802, in alternative implementations, memory 807 can be external to the computer 802.

The application 808 is an algorithmic software engine providing functionality according to particular needs, desires, or particular implementations of the computer 802, particularly with respect to functionality described in the present disclosure. For example, application 808 can serve as one or more components, modules, or applications. Further, although illustrated as a single application 808, the application 808 can be implemented as multiple applications 808 on the computer 802. In addition, although illustrated as integral to the computer 802, in alternative implementations, the application 808 can be external to the computer 802.

The computer 802 can also include a power supply 814. The power supply 814 can include a rechargeable or non-rechargeable battery that can be configured to be either user- or non-user-replaceable. In some implementations, the power supply 814 can include power-conversion or management circuits (including recharging, standby, or another power management functionality). In some implementations, the power-supply 814 can include a power plug to allow the computer 802 to be plugged into a wall socket or another power source to, for example, power the computer 802 or recharge a rechargeable battery.

There can be any number of computers 802 associated with, or external to, a computer system containing computer 802, each computer 802 communicating over network 830. Further, the term “client,” “user,” or other appropriate terminology can be used interchangeably, as appropriate, without departing from the scope of the present disclosure. Moreover, the present disclosure contemplates that many users can use one computer 802, or that one user can use multiple computers 802.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal, for example, a machine-generated electrical, optical, or electromagnetic signal that is generated to encode information for transmission to a receiver apparatus for execution by a data processing apparatus. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed.

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. In one non-limiting example, the terms “about” and “approximately” mean plus or minus 10 percent or less.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” or “electronic computer device” (or equivalent as understood by one of ordinary skill in the art) refer to data processing hardware and encompass all kinds of apparatus, devices, and machines for processing data, including by way of example, a programmable processor, a computer, or multiple processors or computers. The apparatus can also be, or further include special purpose logic circuitry, for example, a central processing unit (CPU), an FPGA (field programmable gate array), or an ASIC (application-specific integrated circuit). In some implementations, the data processing apparatus or special purpose logic circuitry (or a combination of the data processing apparatus or special purpose logic circuitry) can be hardware- or software-based (or a combination of both hardware- and software-based).

The apparatus can optionally include code that creates an execution environment for computer programs, for example, code that constitutes processor firmware, a protocol stack, a database management system, an operating system, or a combination of execution environments. The present disclosure contemplates the use of data processing apparatuses with an operating system of some type, for example LINUX, UNIX, WINDOWS, MAC OS, ANDROID, IOS, another operating system, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code.

A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and apparatus can also be implemented as, special purpose logic circuitry, for example, a CPU, an FPGA, or an ASIC.

Computers for the execution of a computer program can be based on general or special purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device.

Non-transitory computer-readable media for storing computer program instructions and data can include all forms of media and memory devices, magnetic devices, magneto optical disks, and optical memory device. Memory devices include semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Magnetic devices include, for example, tape, cartridges, cassettes, internal/removable disks. Optical memory devices include, for example, digital video disc (DVD), CD-ROM, DVD+/−R, DVD-RAM, DVD-ROM, HD-DVD, and BLURAY, and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special purpose logic circuitry.

To provide for interaction with a user, implementations of the subject matter described in this specification can be implemented on a computer having a display device, for example, a CRT (cathode ray tube), LCD (liquid crystal display), LED (Light Emitting Diode), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity, a multi-touch screen using capacitive or electric sensing, or another type of touchscreen. Other types of devices can be used to interact with the user. For example, feedback provided to the user can be any form of sensory feedback. Input from the user can be received in any form, including acoustic, speech, or tactile input. In addition, a computer can interact with the user by sending documents to and receiving documents from a client computing device that is used by the user.

The term “graphical user interface,” or “GUI,” can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11 a/b/g/n or 802.20 (or a combination of 802.11x and 802.20 or other protocols consistent with the present disclosure), all or a portion of the Internet, another communication network, or a combination of communication networks. The communication network can communicate with, for example, Internet Protocol (IP) packets, Frame Relay frames, Asynchronous Transfer Mode (ATM) cells, voice, video, data, or other information between networks addresses.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A method comprising:
acquiring magnetic resonance (MR) signals from a subject placed in a magnet of a MR scanner, wherein the MR signals are in response to radio frequency (RF) irradiation of the subject using a multi-echo MR imaging sequence;
obtaining a set of MR images from the acquired MR signals wherein each image corresponds to a respective echo of the multi-echo MR imaging sequence; and
geometrically combining at least two MR images from the set of MR images such that a combined image is generated with a first metric of signal-to-noise ratio and a second metric of contrast ratio, both improved as compared to the first metric and the second metric of each of the at least two MR images, wherein said geometrically combining comprises:
generating an inverse representation for each of the at least two MR images; and
summing respective inverse representations of the at least two MR images.

2. The method of claim 1, wherein the said geometrically combining further comprises:
generating an inverse representation of results of said summing.

3. The method of claim 2, further comprising:
generating a display of the combined image, and
providing the display to a medical practitioner.

4. The method of claim 2, wherein generating the inverse representation comprises: performing an inverse operation of pixels of an MR image from the set of MR images.

5. The method of claim 4, further comprising: adding a non-zero constant to the pixels of the MR image before performing the inverse operation of pixels of the MR image.

6. The method of claim 1, wherein the set of MR images are T₂-weighted or T₂*-weighted.

7. The method of claim 1, wherein the multi-echo MR imaging sequence comprises: a SSFP (steady-state free precession) sequence, a MERGE (multiple echo recombined gradient echo) sequence, or a MEDIC sequence (multiple echo data image combination).

8. A magnetic resonance scanner, comprising:
a main magnet configured to generate a volume of magnetic field, the main magnet including a bore area sized to accommodate at least a body part of a subject;
a radio frequency (RF) coil assembly configured to irradiate the body part of the subject in the magnet;
a gradient coil assembly configured to generate gradient pulses that provide perturbations to the volume of magnetic field such that MR signals are emitted from the body part and are subsequently acquired by the coil assembly; and
a control unit in communication with the gradient coils and the coil assembly and configured to drive the RF coil assembly and the gradient coil assembly, and perform operations of:
acquiring the magnetic resonance (MR) signals from the body part of the subject placed in the magnet, wherein the MR signals are in response to radio frequency (RF) irradiation of the subject using a multi-echo MR imaging sequence;
obtaining a set of MR images based on the acquired MR signals wherein each image corresponds to a respective echo of the multi-echo MR imaging sequence; and
geometrically combining at least two MR images from the set of MR images such that a combined image is generated with a first metric of signal-to-noise ratio and a second metric of contrast ratio both improved as compared to the first and second metric of each of the at least two MR images, wherein said geometrically combining comprises:
generating an inverse representation for each of the at least two MR images; and
summing respective inverse representations of the at least two MR images.

9. The MR scanner of claim 8, wherein the said geometrically combining further comprises:
generating an inverse representation of results of said summing.

10. The MR scanner of claim 9, wherein the operations further comprise:
generating a display of the combined image, and
providing the display to a medical practitioner.

11. The MR scanner of claim 9, wherein generating the inverse representation comprises: performing an inverse operation of pixels of an MR image from the set of MR images.

12. The MR scanner of claim 11, wherein the operations further comprise: adding a non-zero constant to the pixels of the MR image before performing the inverse operation of the pixels of the MR image.

13. The MR scanner of claim 8, wherein the set of MR images are T₂-weighted or T₂*-weighted.

14. The MR scanner of claim 8, wherein the multi-echo MR imaging sequence comprises: a SSFP (steady state free precession) sequence, a MERGE (multiple echo recombined gradient echo) sequence, or a MEDIC sequence (multiple echo data image combination).

15. A non-transitory computer-readable medium comprising software instructions which, when executed by one or more computer processors, cause the one or more computer processors to perform operations of:
accessing magnetic resonance (MR) signals from a subject placed in a magnet of a MR scanner, wherein the MR signals are in response to radio frequency (RF) irradiation of the subject using a multi-echo MR imaging sequence;
obtaining a set of MR images from the MR signals wherein each image corresponds to a respective echo of the multi-echo MR imaging sequence; and
geometrically combining at least two MR image from the set of MR images such that a combined image is generated with a first metric of signal-to-noise ratio and a second metric of contrast ratio both improved when compared to the first metric and the second metric of each of the at least two MR images, wherein said geometrically combining comprises:
generating an inverse representation for each of the at least two MR images; and
summing respective inverse representations of the at least two MR images.

16. The non-transitory computer-readable medium of claim 15, wherein the said geometrically combining further comprises:
generating an inverse representation of results of said summing.

17. The non-transitory computer-readable medium of claim 16, wherein the operations further comprise:
generating a display of the combined image, and
providing the display to a medical practitioner.

18. The non-transitory computer-readable medium of claim 16, wherein generating the inverse representation comprises: performing an inverse operation of pixels of an MR image from the set of MR images.

19. The non-transitory computer-readable medium of claim 18, wherein operations further comprises: adding a non-zero constant to the pixels of the MR image before performing the inverse operation of the pixels of the MR image.

20. The non-transitory computer-readable medium of claim 15, wherein the set of MR images are T₂-weighted or T₂*-weighted, and wherein the multi-echo MR imaging sequence comprises: a DESS (dual-echo steady state free precession) sequence, a MERGE (multiple echo recombined gradient echo) sequence, or a MEDIC sequence (multiple echo data image combination).
